(19) United States
(12) Patent Application Publication
(10) Pub. No.: US 2006/0139059 A1
(43) Pub. Date: Jun. 29, 2006

(54) Level shift circuit and method

(76) Inventor: In-Chul Jeong, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/313,860

(22) Filed: Dec. 20, 2005

(30) Foreign Application Priority Data
Dec. 24, 2004 (KR) 2004-112215

(51) Int. Cl. H03K 19/094

(52) U.S. Cl. 326/68

(57) ABSTRACT

We describe various embodiments of a level shift circuit and an associated method that achieve increased responsiveness by simultaneously adjusting the input signal width and shifting the voltage thereby reducing the number of logic gate stages needed for the two operations. A level shift circuit includes a delay unit for delaying an input signal via a plurality of stages to generate a plurality of delayed signals, and a signal width adjusting and level shifting unit for generating a first level of signal that is level-shifted in response to the input signal and a first delayed signal having the same phase as that of the input signal and generating a second level of signal in response to a second delayed signal having a different phase from that of the input signal.

### RELATED APPLICATION

We claim priority from Korean Patent Application No. 10-2004-0112215 filed Dec. 24, 2004, the disclosure of which we incorporate by reference.

### BACKGROUND

1. Field

We describe a level shift circuit and, more particularly, we describe an improved level shift circuit and an associated method to increase responsiveness.

2. Related Art

A level shift circuit is commonly used in a semiconductor integrated circuit to generate an output voltage that is higher than, or shifted from, an input voltage. The level shift circuit is widely used as a word line driver, a block select circuit, or the like in a semiconductor memory device.

A cell transistor in a semiconductor memory is designed to have a relatively greater threshold voltage VTH than a typical transistor, to reduce leakage current. When the cell transistor is turned on, charge accumulated in a cell capacitor is loaded on a bit line (read operation), or charge flows from the bit line to the cell capacitor (write operation).

Due to a large threshold voltage of the cell transistor, a rise in the voltage level of the bit line may be undetectable by a sense amplifier. To solve this problem, the word line is driven with an internal boost voltage VPP which is higher than a power supply voltage VCC, as an enable voltage for the word line.

Since the boost voltage VPP is generated by accumulation of charge due to the power supply voltage VCC, the boost voltage VPP consumes more power than the supply voltage VCC. Accordingly, when low power consumption is required, the boost voltage VPP is used as little as possible.

In order to suppress power consumption by the boost voltage VPP, we propose a level shift circuit that outputs the boost voltage VPP only when needed.

A control circuit is connected to an input of the level shift circuit to adjust the width of signals input to the level shift circuit.

Examples of presently-used control circuits include circuits that generate a signal and the like having a delayed rising edge with respect to an input signal, a signal having a delayed falling edge with respect to an input signal, a signal enabled in synchronization with a rising edge of an input signal, and a signal enabled in synchronization with a falling edge of an input signal.

FIG. 1 is a detailed circuit diagram of a level shift circuit and a control circuit for delaying a rising edge of an input signal.

As shown in FIG. 1, the control circuit 1 includes an even number of serially-connected inverters INV1 to INV4, a NAND gate for logically manipulating an input signal IN and a delayed version of the input signal IN from the inverters INV1 to INV4, and an inverter INV5 for inverting the output of the NAND gate. The level shift circuit 2 includes an inverter INV6 for inverting the signal output from the inverter INV5. A first NMOS transistor NMOS1 is connected in series between a control node NA and a ground voltage VSS and operates responsive to the signal output from the inverter INV5. A second NMOS transistor NMOS2 is connected in series between an output node NB and the ground voltage VSS and operates responsive to a signal output from the inverter INV6. A first PMOS transistor PMOS1 is connected in series between a boost voltage VPP and the control node NA and operates responsive to a voltage level at the output node NB. A second PMOS transistor PMOS2 is connected in series between the boost voltage VPP and the output node NB and operates responsive to a voltage level at the control node NA.

Operation of the circuit of FIG. 1 will be described with reference to a waveform diagram of FIG. 2.

An input signal IN is at a low level, the control node NA is at the boost voltage VPP, and the output node NB is at the ground voltage VSS.

When the input signal IN transitions from the low level to a high level at TR, the inverters INV1 to INV4 output a high level signal at T4, the NAND gate outputs a low level signal at T5, the inverter INV5 outputs a high level signal at T6, and the inverter INV6 outputs a low level signal at T7.

At T6, the first NMOS transistor NMOS1 is turned on, allowing current to flow through the first NMOS transistor NMOS1, and lowering the voltage level at the control node NA. At T7, the voltage at the control node NA becomes the ground voltage VSS, the second PMOS transistor PMOS2 is turned on responsive to the voltage at the control node NA, and the second NMOS transistor NMOS2 is turned off, such that the voltage at the output node NB rises to the boost voltage VPP at T8.

This state is maintained until the inverter INV5 outputs a low level signal and the inverter INV6 outputs a high level signal at T13.

At T13, the first NMOS transistor NMOS1 is turned off and the second NMOS transistor NMOS2 is turned on, allowing current to flow through the second NMOS transistor NMOS2 and lowering the voltage level at the output node NB. At T14, the output node NB is reduced to the ground voltage VSS.

As described above, the control circuit of FIG. 1 delays the rising edge of the input signal by a delay D2 corresponding to a delay of the inverters INV1 to INV4.

However, the conventional control circuit and level shift circuit further delay the input signal by a delay D1 corresponding to a delay of the four stages of logic gates, i.e., the NAND gate, the inverter INV5, the NMOS transistor NMOS1, and the PMOS transistor PMOS2, and output a delayed signal as shown in the waveform diagram.

Since an input signal applied to the conventional circuit further passes through the four stages of logic gates in addition to the inverters of the control circuit before being output, the delay time increases degrading responsiveness.

### SUMMARY

We describe various embodiments of a level shift circuit and an associated method that achieves increased responsiveness by simultaneously adjusting the input signal width and level shifting thereby reducing the number of logic gate stages needed for the two operations.

A level shift circuit comprises a delay unit for delaying an input signal via a plurality of stages to generate a plurality of delayed signals; and a signal width adjusting and level shifting unit for generating a first level of signal that is level-shifted in response to the input signal and a first delayed signal having the same phase as that of the input signal and generating a second level of signal in response to a second delayed signal having a different phase from that of the input signal.

A level shift circuit comprises a delay unit for delaying an input signal via a plurality of stages to generate a plurality of delayed signals; and a signal width adjusting and level shifting unit for generating a first level of shifted signal that is level-shifted in response to the input signal and generating a second level of signal in response to first and second delayed signals having a different phase from that of the input signal.

A level shift circuit comprises a delay unit for delaying an input signal via a plurality of stages to generate a plurality of delayed signals; and a signal width adjusting and level shifting unit for generating a first level of signal in response to the input signal and a first delayed signal having a different phase from that of the input signal and generating a second level of signal in response to a second delayed signal having a different phase from that of the input signal and a third delayed signal having the same phase as that of the input signal.

A level shift method comprises a delaying step of generating a plurality of delayed signals from an input signal; a signal width adjusting step of adjusting the width of an output signal by transitioning the state of the output signal according to states of the input signal and the plurality of delayed signals; and a level shifting step of allowing the output signal to have a first shifted level when the output signal is in a first state and to have a second level when the output signal is in a second state, and outputting the resultant output signal.

### BRIEF DRAWINGS DESCRIPTION

The foregoing and other objects, features, and advantages of the level shift circuit and the associated method will be apparent from the more particular description illustrated in the accompanying drawing. The drawing is not necessarily to scale, emphasis instead being placed on illustrating the level shift circuit and associated method.

FIG. 1 is a detailed circuit diagram of a level shift circuit and a control circuit for delaying a rising edge of an input signal.

FIG. 2 is a waveform diagram illustrating operations of the circuits of FIG. 1.

FIG. 3 is an internal block diagram of a level shift circuit according to an exemplary embodiment.

FIG. 4 is a detailed circuit diagram of a level shift circuit for generating a signal for delaying a rising edge of an input signal according to a first embodiment of FIG. 3.

FIG. 5 is a signal waveform diagram illustrating the operation of the circuit of FIG. 4.

FIG. 6 is a detailed circuit diagram of a level shift circuit for generating a signal for delaying a rising edge of an input signal according to a second embodiment of FIG. 3.

FIG. 7 is a signal waveform diagram illustrating the operation of the circuit of FIG. 6.

FIG. 8 is a detailed circuit diagram of a level shift circuit for delaying a falling edge of an input signal according to a third embodiment of FIG. 3.

FIG. 9 is a signal waveform diagram illustrating the operation of the circuit of FIG. 8.

FIG. 10 is a detailed circuit diagram of a level shift circuit for delaying a falling edge of an input signal according to a fourth embodiment of FIG. 3.

FIG. 11 is a signal waveform diagram illustrating the operation of the circuit of FIG. 10.

FIG. 12 is a detailed circuit diagram of a level shift circuit for generating a signal enabled in synchronization with a rising edge of an input signal according to a fifth embodiment of FIG. 3.

FIG. 13 is a signal waveform diagram illustrating the operation of the circuit of FIG. 12.

FIG. 14 is a detailed circuit diagram of a level shift circuit for generating a signal enabled in synchronization with a falling edge of an input signal according to a sixth embodiment of FIG. 3.

FIG. 15 is a signal waveform diagram illustrating the operation of the circuit of FIG. 14.

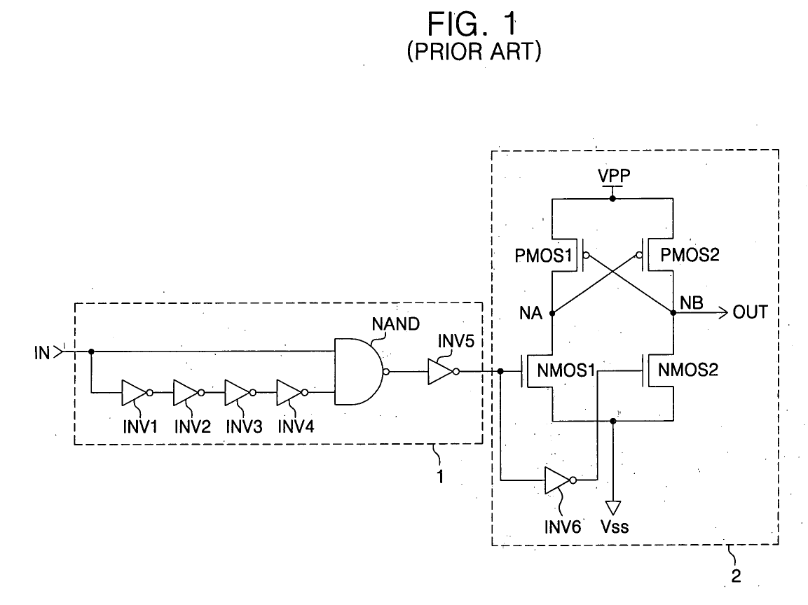

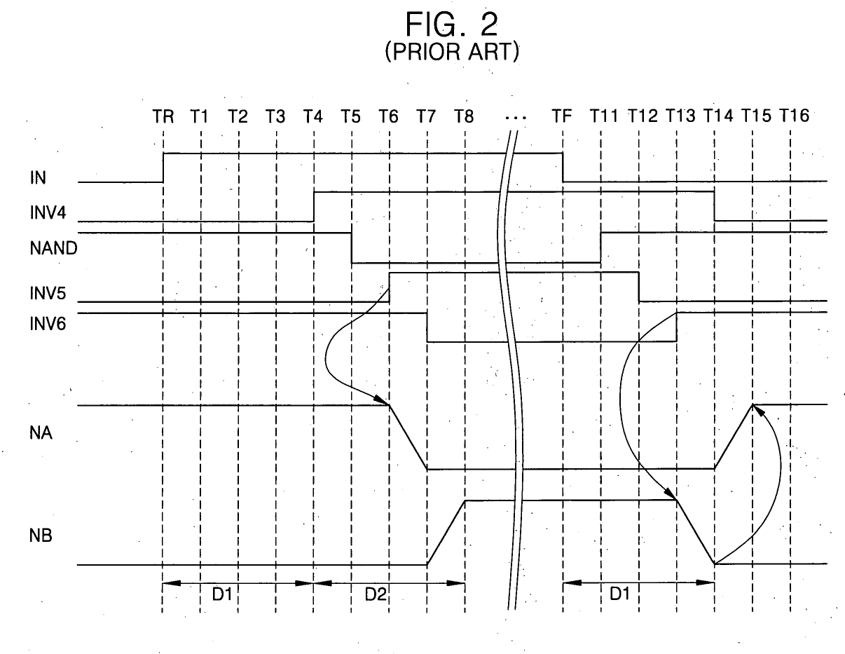

### DETAILED DESCRIPTION

We describe a level shift circuit and method with reference to the accompanying drawings.

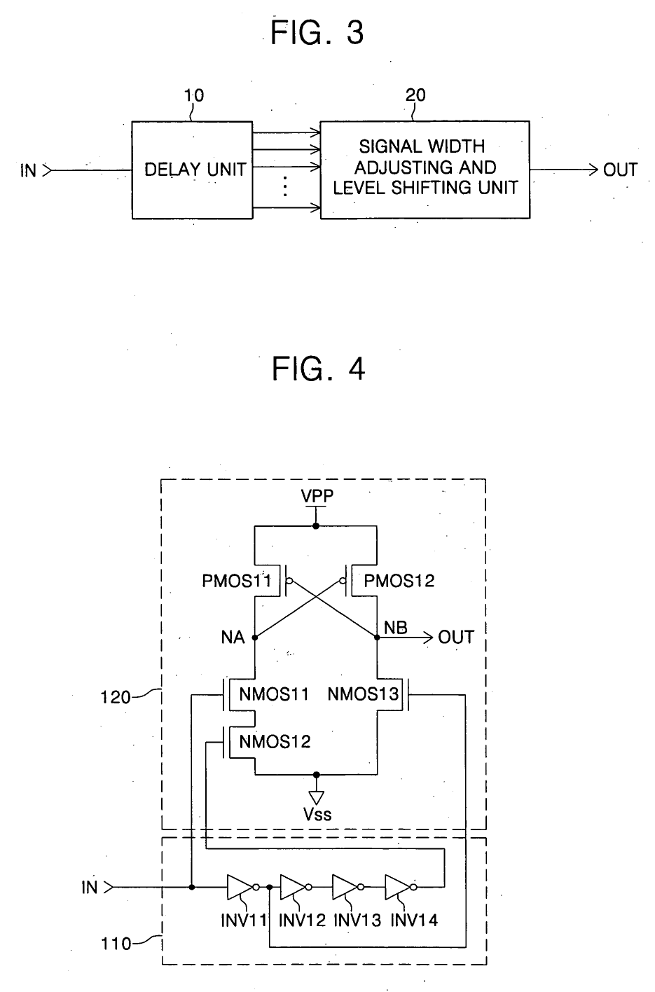

FIG. 3 is an internal block diagram of a level shift circuit according to an exemplary embodiment.

Referring to FIG. 3, the level shift circuit includes a delay unit 10 and a signal width adjusting and level shifting unit 20.

The delay unit 10 delays an input signal via a plurality of stages to generate a plurality of delayed signals having several delay times and phases.

The signal width adjusting and level shifting unit 20 adjusts the width of the input signal by combining the plurality of delayed signals. The unit 20 allows an output signal to have a boost voltage VPP when the input signal is at a high level and to have a ground voltage VSS when the input signal is at a low level.

For example, the signal width adjusting and level shifting unit 20 combines the plurality of delayed signals and generates a signal having a delayed rising edge with respect to the input signal, a signal having a delayed falling edge with respect to the input signal, a signal enabled in synchronization with the rising edge of the input signal, and a signal enabled in synchronization with the falling edge of the input signal.

We will now describe the signal having a delayed rising edge with respect to the input signal, the signal having a delayed falling edge with respect to the input signal, the signal enabled in synchronization with the rising edge of the input signal, and the signal enabled in synchronization with the falling edge of the input signal in more detail.

FIG. 4 is a detailed circuit diagram of a level shift circuit for generating a signal for delaying a rising edge of an input signal according to a first embodiment of FIG. 3.

As shown in FIG. 4, a delay unit 110 delays an input signal IN with, e.g., an even number of stages to generate an even number of delayed signals. A signal width adjusting and level shifting unit 120 generates a signal transitioned from a low level to a high level in response to the input signal IN and a delayed signal from the last stage INV14 having the same phase as that of the input signal IN. And the unit 120 generates a signal transitioned from a high level to a low level in response to a delayed signal from an odd stage INV11 having a different phase from that of the input signal IN.

The delay unit 110 includes an even number of serially-connected inverters INV11 to INV14. The signal width adjusting and level shifting unit 120 includes first and second NMOS transistors NMOS11 and NMOS12 connected in series between a control node NA and a ground voltage VSS. The NMOS transistors NMOS11 and NMOS12 respond to the input signal IN and an output signal of the fourth inverter INV14, respectively. A third NMOS transistor NMOS13 is connected in series between an output node NB and the ground voltage VSS. The NMOS transistor NMOS13 responds to an output signal of the first inverter INV11. A first PMOS transistor PMOS11 is connected in series between the boost voltage VPP and the control node NA. The PMOS transistor PMOS11 responds to a voltage level at the output node NB. And a second PMOS transistor PMOS12 is connected in series between the boost voltage VPP and the output node NB and operates responsive to a voltage level at the control node NA.

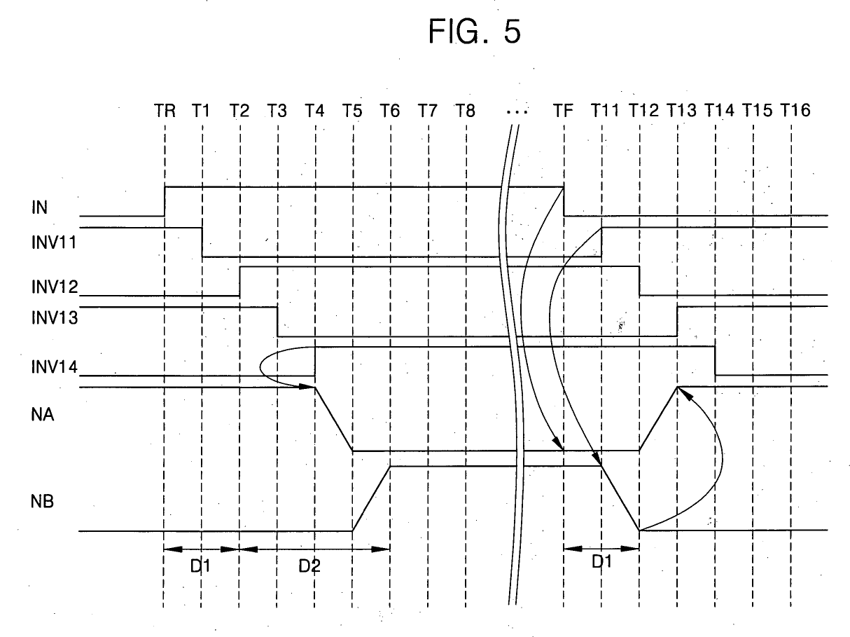

FIG. 5 is a waveform diagram illustrating the operation of the level shift circuit of FIG. 4. The operation of the circuit shown in FIG. 4 will be described with reference to FIG. 5.

It is assumed that the input signal IN is enabled from TR to TF. That is, the input signal IN transitions from a low level to a high level at TR and from a high level to a low level at TF.

The first inverter INV11 generates a signal transitioned from a high level to a low level at T1 and from a low level to a high level at T11. The second inverter INV12 generates a signal transitioned from a low level to a high level at T2 and from a high level to a low level at T12. The third inverter INV13 generates a signal transitioned from a high level to a low level at T3 and from a low level to a high level at T13. And the fourth inverter INV14 generates a signal transitioned from a low level to a high level at T4 and from a high level to a low level at T14.

In the standby state, the first and second NMOS transistors NMOS11 and NMOS12 are turned off and the third NMOS transistor NMOS13 is turned on, allowing current to flow through the third NMOS transistor NMOS13 and lowering a voltage level at the output node NB to the ground voltage VSS. Accordingly, the first PMOS transistor PMOS11 is turned on in response to the ground voltage VSS, allowing current to flow to the first PMOS transistor PMOS11 and increasing a voltage level at the control node NA to the level of the boost voltage VPP.

In the standby state, the output node NB of the level shift circuit has a level of the ground voltage VSS and the control node NA has a level of the boost voltage VPP.

The level shift circuit in the standby state operates as follows.

At TR, the first NMOS transistor NMOS11 is turned on, the second NMOS transistor NMOS12 is turned off, and the third NMOS transistor NMOS13 is turned on, allowing current to flow through the third NMOS transistor NMOS13. That is, the level shift circuit operates in the same manner as in the standby state, such that the output node NB has a level of the ground voltage VSS and the control node NA has a level of the boost voltage VPP.

This state is maintained and does not begin to change until the fourth inverter INV14 outputs a high level signal at T4.

That is, at T4, the first and second NMOS transistors NMOS11 and NMOS12 are turned on and the third NMOS transistor NMOS13 is turned off, allowing current to flow through the first and second NMOS transistors NMOS11 and NMOS12 and gradually lowering a voltage level at the control node NA.

At T5, the voltage level at the control node NA becomes the same as the ground voltage VSS, thereby turning the second PMOS transistor PMOS12 on. Current flows through the second PMOS transistor PMOS12, gradually increasing the voltage level at the output node NB.

At T6, the voltage level at the output node NB becomes the same as the boost voltage VPP and the level shift circuit generates an output signal OUT having the boost voltage VPP at the output node NB.

This state is maintained until TF. The first, second and third NMOS transistors NMOS11, NMOS12 and NMOS13 are turned off at TF and current no longer flows through the first and second NMOS transistors NMOS11 and NMOS12. That is, the voltage level at the output node NB is fixed.

When the first inverter INV11 outputs a high level signal at T11, the third NMOS transistor NMOS13 is turned back on and current flows through the third NMOS transistor NMOS13, lowering the voltage level at the output node NB.

At T12, the voltage level at the output node NB becomes the same as the ground voltage VSS again and the level shift circuit generates an output signal OUT having the ground voltage VSS at the output node NB.

As such, the level shift circuit of FIG. 4 combines the output signal of the first inverter INV11 with the output signal of the fourth inverter INV14 to delay a rising edge of the input signal by a delay D2 corresponding to a delay factor of the inverters INV11 to INV14 in the delay unit 110.

In addition, the level shift circuit reduces the input signal delay D1 due to the logic gates (e.g., the first NMOS transistor NMOS11 and the second PMOS transistor PMOS12) by performing the input signal width adjusting operation and the input signal level shifting operation in combination and by reducing the number of stages of the logic gates needed for the two operations. Accordingly, the level shift circuit of FIG. 4 has increased responsiveness.

However, in the level shift circuit of FIG. 4, there is a section in which both the second PMOS transistor PMOS12 and the third NMOS transistor NMOS13 are turned off in the period F between T2 and T5. During this period, no current flows through the output node NB, which may cause the output node NB to float.

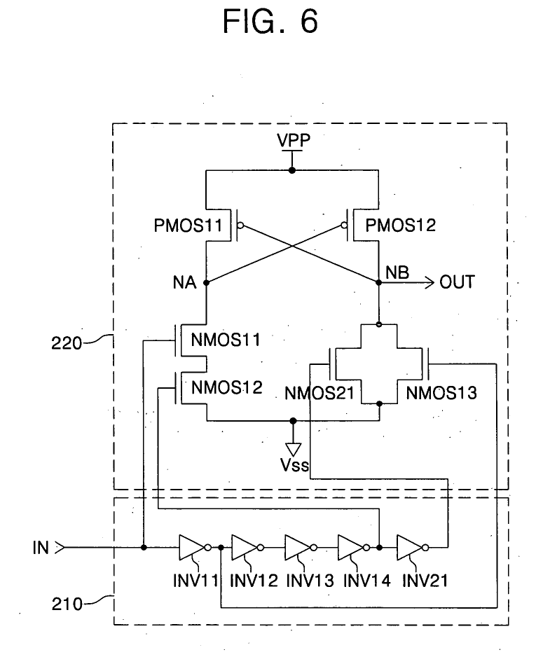

By using the level shift circuit of FIG. 6, the present invention is capable of preventing the generation of the period F in which the output node NB floats, such as the period between T2 and T5 of FIG. 4.

As shown in FIG. 6, the level shift circuit further includes a fifth inverter INV21 connected in series with the fourth inverter INV14. And a fourth NMOS transistor NMOS21 connected in parallel with the third NMOS transistor NMOS13 and responding to an output signal of the fifth inverter INV21.

Components of FIG. 6 having the same configuration and operation as those shown in FIG. 4 are given with the same reference numerals as those of FIG. 4 and detailed descriptions thereof will be omitted.

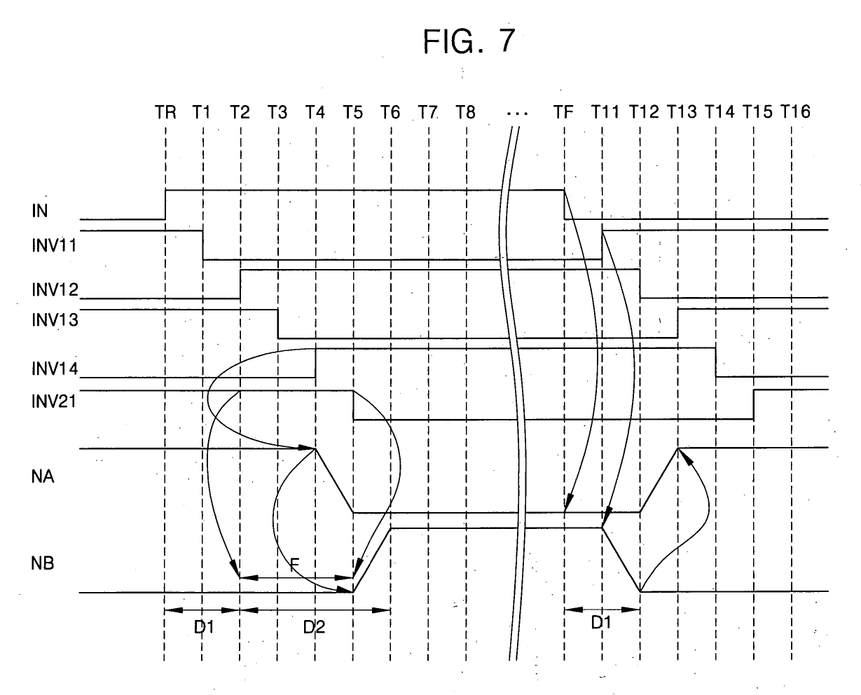

The operation of the circuit shown in FIG. 6 will be now described with reference to the waveform diagram of FIG. 7.

At T2, the input signal IN is at a high level, the first inverter INV11 outputs a low level signal, the second inverter INV12 outputs a low level signal, the third inverter INV13 outputs a high level signal, the fourth inverter INV14 outputs a low level signal, and the fifth inverter INV21 outputs a high level signal.

Accordingly, when the second PMOS transistor POMS12 is turned off, the third NMOS transistor NMOS13 is turned off but the fourth NMOS transistor NMOS21 is turned on, allowing current to flow through the fourth NMOS transistor NMOS21.

The current flowing through the fourth NMOS transistor NMOS21 is applied to the output node NB, thereby preventing the output node NB from floating.

Operations of the fourth NMOS transistor NMOS21 at T3 and T4 are the same as that at T2.

In addition, at T4, the first and second NMOS transistors NMOS11 and NMOS12 is turned on, allowing current to flow through the second PMOS transistor PMOS12 and lowering a voltage level at the control node NA.

At T5, the fourth NMOS transistor NMOS21 is turned off. However, the voltage level at the control node NA becomes the ground voltage VSS level, thereby turning the second PMOS transistor PMOS12 on and allowing current to flow through the second PMOS transistor PMOS12.

Accordingly, the output node NB is applied with current flowing through the second PMOS transistor PMOS12. The output node NB does not float because of the current flowing through the fourth NMOS transistor NMOS21. The voltage level at the control node NA is lowered in the period F between T2 and T5.

As described above, the circuit of FIG. 6 allows the fourth NMOS transistor NMOS21 to be turned on even though both the second PMOS transistor PMOS12 and the third NMOS transistor NMOS13 are turned off, preventing the output node NB from floating.

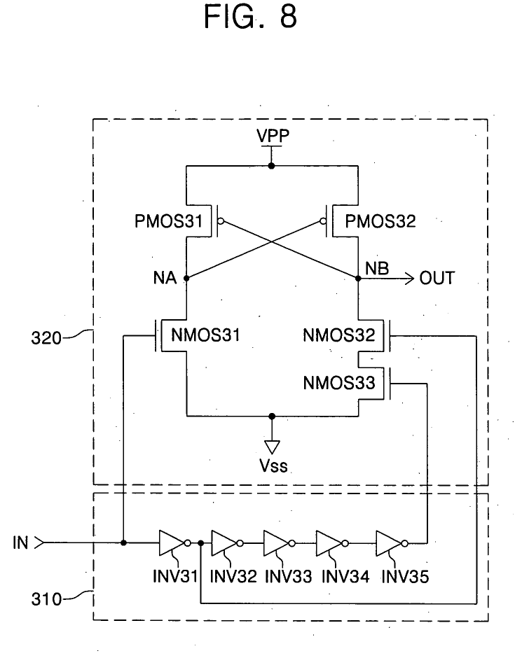

FIG. 8 is a detailed circuit diagram of a level shift circuit for delaying a falling edge of an input signal according to a third embodiment of FIG. 3.

As shown in FIG. 8, a delay unit 310 delays an input signal IN via an odd number of stages to generate an odd number of delayed signals. A signal width adjusting and level shifting unit 320 generates a signal transitioned from a low level to a high level in response to the input signal IN and, a signal transitioned from a high level to a low level in response to delayed signals from at least two odd stages INV31 and INV35 having a different phase from that of the input signal IN.

The delay unit 310 includes an odd number of inverters INV31 to INV35. The signal width adjusting and level shifting unit 320 includes a first NMOS transistor NMOS31 connected in series between a control node NA and a ground voltage VSS and responding to the input signal IN. The second and third NMOS transistors NMOS32 and NMOS33 are connected in series between an output node NB and the ground voltage VSS. The second and third NMOS transistors NMOS32 and NMOS33 respond to output signals of the first and fifth inverters INV31 and INV35, respectively. A first PMOS transistor PMOS31 is connected in series between a boost voltage VPP and the control node NA. The PMOS transistor PMOS31 responds to the voltage level at the output node NB. A second PMOS transistor PMOS32 is connected in series between the boost voltage VPP and the output node NB and responds to the voltage level at the control node NA.

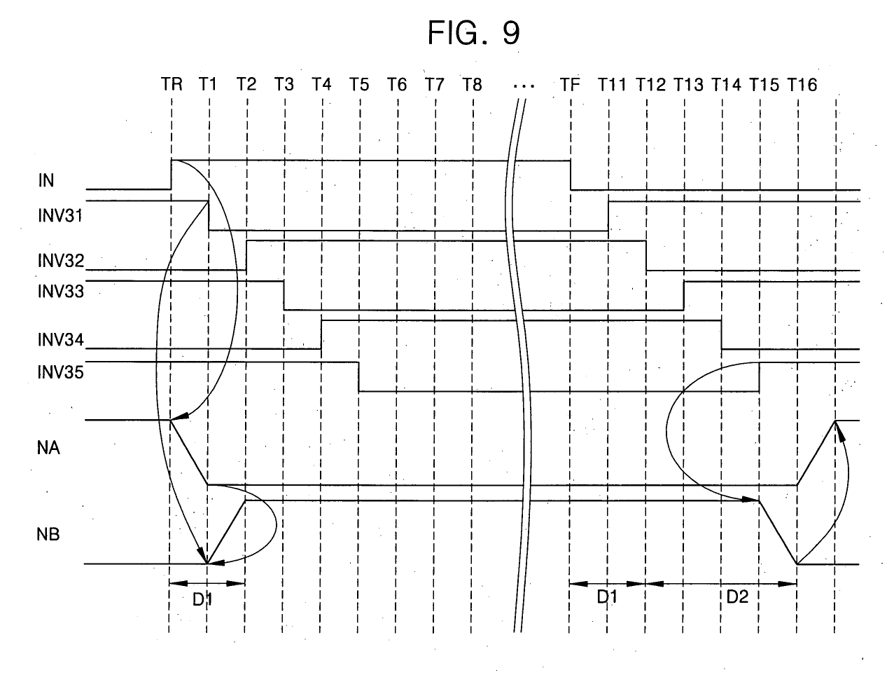

The operation of the level shift circuit will be now described with reference to the waveform diagram of FIG. 9.

It is assumed that the input signal IN is enabled from TR to TF. That is, the input signal IN transitions from a low level to a high level at TR and from a high level to a low level at TF.

The first inverter INV31 generates a signal transitioned from a high level to a low level at T1 and from a low level to a high level at T11. The second inverter INV32 generates a signal transitioned from a low level to a high level at T2 and from a high level to a low level at T12. The third inverter INV33 generates a signal transitioned from a high level to a low level at T3 and from a low level to a high level at T13. The fourth inverter INV34 generates a signal transitioned from a low level to a high level at T4 and from a high level to a low level at T14. And the fifth inverter INV35 generates a signal transitioned from a high level to a low level at T5 and from a low level to a high level at T15.

First, the level shift circuit in a standby state has the following signal output states.

In the standby state, the first and second NMOS transistors NMOS31 and NMOS32 are turned off and the third NMOS transistor NMOS33 is turned on, allowing current to flow through the third NMOS transistor NMOS33 and lowering the voltage level at the output node NB to the ground voltage VSS. In addition, the first PMOS transistor PMOS31 is turned on in response to the ground voltage VSS, increasing the voltage level at the control node NA to a level of the boost voltage VPP by means of the first PMOS transistor PMOS31.

As such, the output node NB of the level shift circuit has a level of the ground voltage VSS and the control node NA has a level of the boost voltage VPP in a standby state.

At TR, the first NMOS transistor NMOS31 is turned on and the second and third NMOS transistors NMOS32 and NMOS33 are turned on, allowing current to flow through the first NMOS transistor NMOS31 and the second and third NMOS transistors NMOS32 and NMOS33, and gradually lowering the voltage level at the control node NA.

At T1, the control node NA becomes the ground voltage VSS, and the second PMOS transistor PMOS32 is turned on and the second NMOS transistor NMOS32 is turned off, allowing current to flow through the second and PMOS transistor PMOS32 and gradually increasing the voltage level at the output node NB.

At T2, the voltage level at the output node NB becomes the boost voltage VPP level and the level shift circuit generates an output signal OUT having the boost voltage VPP at the output node NB.

This state does not change until the fifth inverter INV35 outputs a high level signal at T15.

At T15, the first NMOS transistor NMOS31 is turned off, the second and third NMOS transistors NMOS32 and NMOS33 are turned on, allowing current to flow through the third NMOS transistor NMOS33 and gradually lowering the voltage level at the output node NB.

At T16, the voltage level at the output node NB becomes the ground voltage VSS level and the level shift circuit generates back the output signal OUT having the ground voltage VSS at the output node NB.

As described above, the level shift circuit of FIG. 8 delays a falling edge of the input signal IN by a delay D2 corresponding to a delay factor of the inverters INV32 to INV35 in the delay unit 310 by combining the input signal IN, the output signal of the first inverter INV31 and the output signal of the fifth inverter INV35.

In addition, the level shift circuit reduces an input signal delay D1, caused by the logic gates (e.g., the first NMOS transistor NMOS31 and the second PMOS transistor PMOS32), by performing the input signal width adjusting operation and the input signal level shift operation in combination and reducing the number of stages of the logic gates needed for the two operations. Accordingly, the level shift circuit of FIG. 8 provides has improved responsiveness, as in the circuit of FIG. 4.

In the level shift circuit of FIG. 8, the first PMOS transistor PMOS31 and the first NMOS transistor NMOS31 are all turned off such that the control node NA may float during the period between TF and T15.

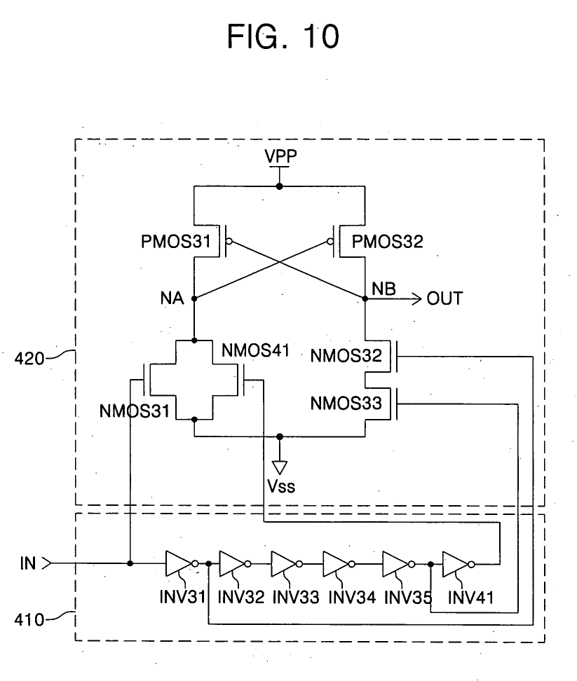

The present invention prevents the control node NA from floating in the period between TF and T16 of FIG. 8 using the level shift circuit of FIG. 10.

The level shift circuit of FIG. 10 further includes a sixth inverter INV41 connected in series to the fifth inverter INV35 of FIG. 8. And a fourth NMOS transistor NMOS41 is connected in parallel to the first NMOS transistor NMOS31 and operates responsive to the output signal of the fourth inverter INV41.

The components of FIG. 10 that have the same configuration and perform the same operation as those shown in FIG. 8 are given with the same reference numerals as in FIG. 8 and their detailed descriptions are omitted.

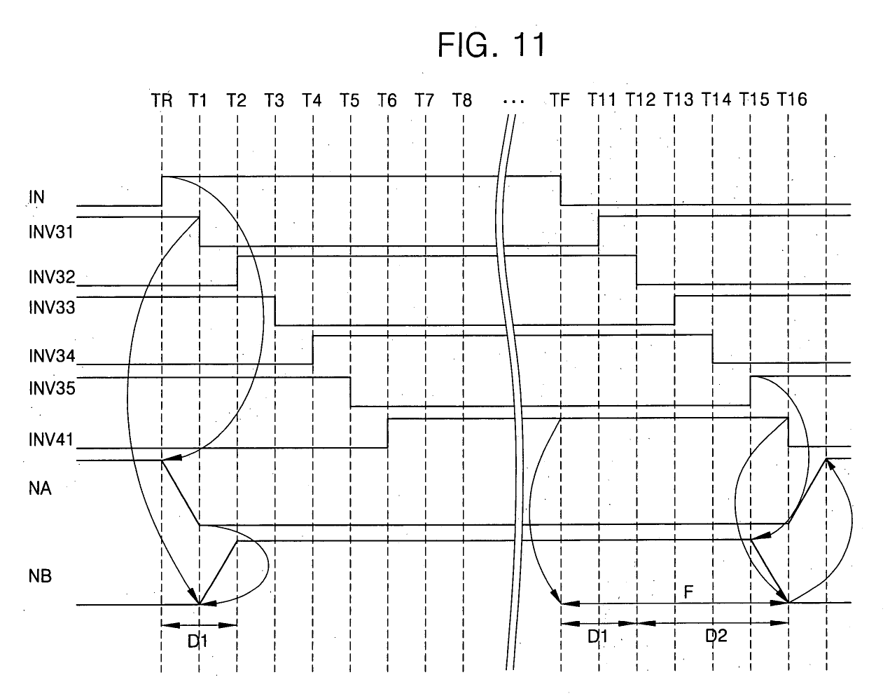

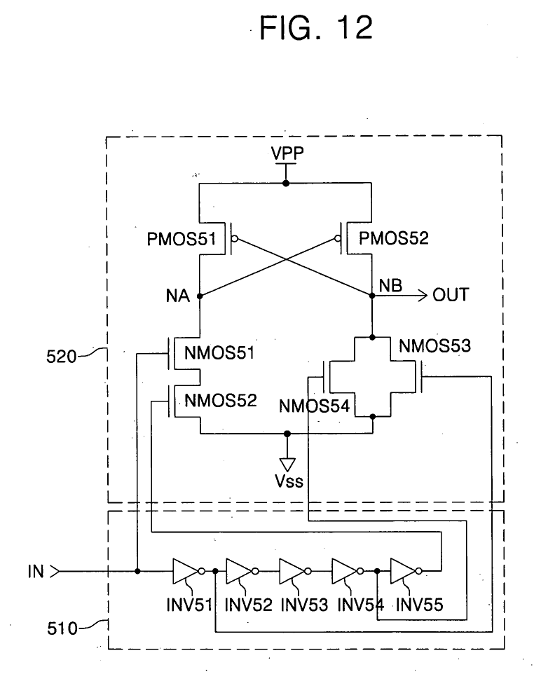

Referring to a TF, FIG. 11, when the first PMOS transistor POMS31 is turned off, the first NMOS transistor NMOS31 is turned off, but the fourth NMOS transistor NMOS41 is turned on, allowing current to flow through the fourth NMOS transistor NMOS41.

Accordingly, the control node NA does not float because of the current flowing through the fourth NMOS transistor NMOS41.

The operation at T11 to T14 is the same as at TF. The voltage level at the output node NB changes when the fifth inverter INV35 outputs a high level signal at T15.

That is, at T15, the first NMOS transistor NMOS31 is turned off and the second to fourth NMOS transistors NMOS32 to NMOS41 are turned on, allowing current to flow through each of the fourth NMOS transistor NMOS41 and the second and third NMOS transistors NMOS32 and NMOS33.

The control node NA does not float because of the current flowing through the fourth NMOS transistor NMOS41 and the voltage level at the output node NB is lower.

At T16, the voltage level at the output node NB becomes the ground voltage VSS level, turning the first PMOS transistor PMOS31 on and allowing current to flow through the first PMOS transistor PMOS31. Accordingly, the output node NB is applied with the current flowing through the first PMOS transistor PMOS31, and the control node NA does not float.

FIG. 12 is a detailed circuit diagram of a level shift circuit for generating a signal enabled in synchronization with a rising edge of an input signal according to a fifth embodiment of FIG. 3.

As shown in FIG. 12, a delay unit 510 delays an input signal IN via an odd number of stages to generate an odd number of delayed signals. A signal width adjusting and level shifting unit 520 generates a signal transitioned from a low level to a high level in response to the input signal IN and a delayed signal from an odd stage INV55 having a different phase from that of the input signal IN, and a signal transitioned from a high level to a low level in response to a delayed signal from an odd stage INV51 having a different phase from that of the input signal IN and a delayed signal from an even stage INV54 having the same phase as that of the input signal IN.

The delay unit 510 includes an odd number of serially-connected inverters INV51 to INV55. The signal width adjusting and level shifting unit 520 includes first and second NMOS transistors NMOS51 and NMOS52 connected in series between a control node NA and a ground voltage VSS. The NMOS transistors NMOS51 and NMOS52 respond to the input signal IN and an output signal from the fifth inverter INV55, respectively. Third and fourth NMOS transistors NMOS53 and NMOS54 are connected in parallel between an output node NB and the ground voltage VSS and respond to output signals of the first and fourth inverters INV51 and INV54, respectively. A first PMOS transistor PMOS51 is connected in series between a boost voltage VPP and the control node NA and responds to a voltage level at the output node NB. And a second PMOS transistor PMOS52 is connected in series between the boost voltage VPP and the output node NB and responds to a voltage level at the control node NA.

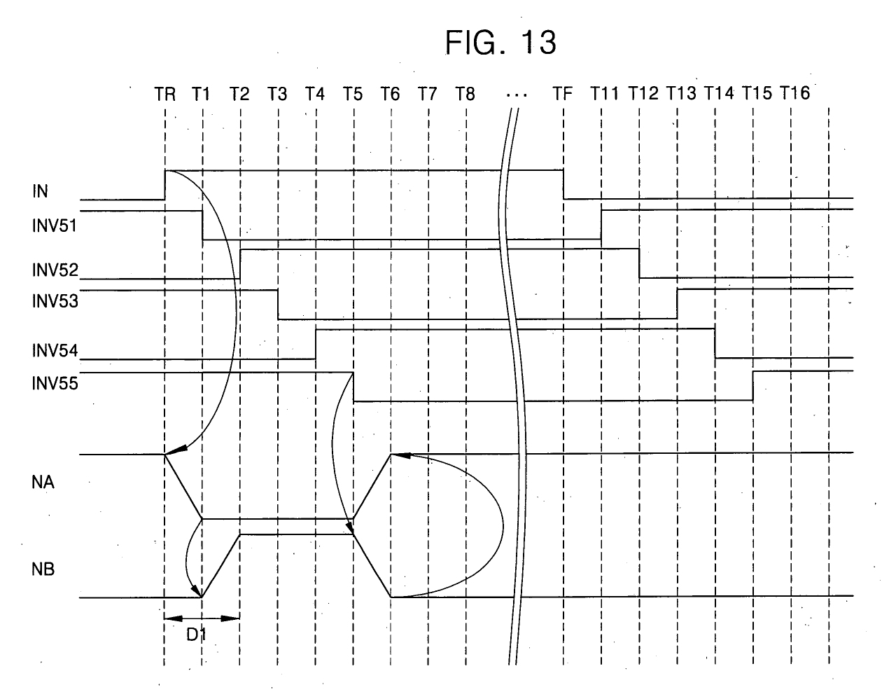

The operation of the circuit shown in FIG. 12 will be now described with reference to the waveform diagram of FIG. 13.

It is assumed that the input signal IN is enabled from TR to TF. That is, the input signal IN transitions from a low level to a high level at TR and from a high level to a low level at TF.

Accordingly, the first inverter INV51 generates a signal transitioned from a high level to a low level at T1 and from a low level to a high level signal at T11. The second inverter INV52 generates a signal transitioned from a low level to a high level at T2 and from a high level to a low level at T12. The third inverter INV53 generates a signal transitioned from a high level to a low level at T3 and from a low level to a high level at T13. The fourth inverter INV54 generates a signal transitioned from a low level to a high level at T4 and from a high level to a low level at T14. And the fifth inverter INV55 generates a signal transitioned from a high level to a low level at T5 and from a low level to a high level at T15.

In the standby state, the first and fourth NMOS transistors NMOS51 and NMOS54 are turned off and the second and third NMOS transistors NMOS52 and NMOS53 are turned on, allowing current to flow through the third NMOS transistor NMOS53. Accordingly, a voltage level at the output node NB is lower to the ground voltage VSS, turning the first PMOS transistor PMOS51 on and increasing the voltage level at the control node NA to the boost voltage VPP.

As such, the output node NB of the level shift circuit in the standby state has a voltage level of the ground voltage VSS and the control node NA has a voltage level of the boost voltage VPP.

At TR, the first NMOS transistor NMOS51 and the second NMOS transistor NMOS52 are turned on, allowing current to flow through the first and second NMOS transistors NMOS51 and NMOS52 and lowering the voltage level at the control node NA.

At T1, the control node NA becomes the ground voltage VSS, turning the second PMOS transistor PMOS52 on and allowing current to flow through the second PMOS transistor PMOS52 to increase the voltage level at the output node NB.

At T2, the voltage level at the output node NB becomes the boost voltage VPP level and the level shift circuit generates an output signal OUT having the boost voltage VPP at the output node NB.

This state is continuously kept and begins to change when the fifth inverter INV55 generates a signal at a low level at T5.

That is, at T5, the fourth NMOS transistor NMOS54 is turned on and current flows through the fourth NMOS transistor NMOS54, lowering the voltage level at the output node NB.

At T6, the voltage level at the output node NB becomes back the ground voltage VSS level and the level shift circuit generates an output signal OUT having the ground voltage VSS at the output node NB.

As described above, the level shift circuit of FIG. 12 combines the input signal IN, the output signal of the first inverter INV51, the output signal of the fourth inverter INV54, and the output signal of the fifth inverter INV55 to generate a signal synchronized with the rising edge and enabled during a delay D2 corresponding to a delay factor of a predetermined number of inverters INV52 to INV54 in the delay unit 510.

The level shift circuit reduces the input signal delay D1 caused by the logic gates (e.g., the first and second NMOS transistors NMOS51 and NMOS52 and the second PMOS transistor PMOS52) by performing the input signal width adjusting operation and the input signal level shifting operation in combination and reducing the number of stages of the logic gates needed for the two operations. Accordingly, the level shift circuit of FIG. 12 provides improved responsiveness, as in FIG. 4.

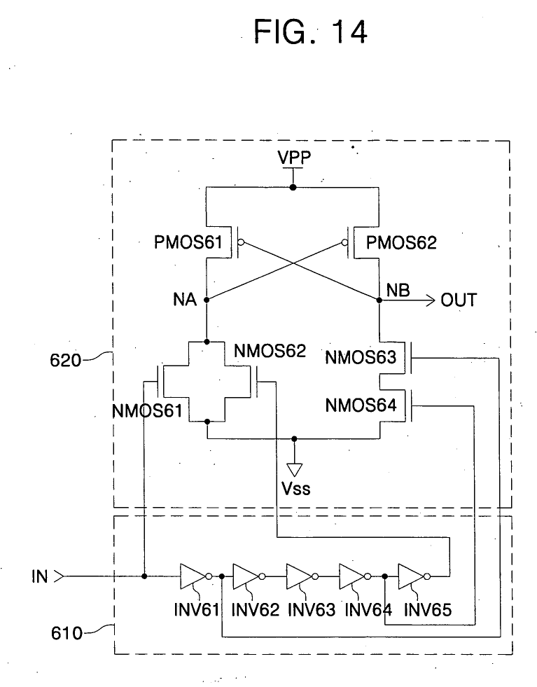

FIG. 14 is a detailed circuit diagram of a level shift circuit for generating a signal enabled in synchronization with a falling edge of an input signal according to a sixth embodiment of FIG. 3.

As shown in FIG. 14, a delay unit 610 delays an input signal IN via an odd number of stages to generate an odd number of delayed signals. A signal width adjusting and level shifting unit 620 generates a signal transitioned from a high level to a low level in response to the input signal IN and a delayed signal from an odd stage INV65 having a different phase from that of the input signal IN. The unit 620 generates a signal transitioned from a low level to a high level in response to a delayed signal from an odd stage INV61 having a different phase from that of the input signal IN and a delayed signal from an even stage INV64 having the same phase as that of the input signal IN.

The delay unit 610 includes an odd number of serially-connected inverters INV61 to INV65. The signal width adjusting and level shifting unit 620 is composed of first and second NMOS transistors NMOS61 and NMOS62 connected in parallel between a control node NA and a ground voltage VSS. The NMOS transistors NMOS61 and NMOS62 respond to the input signal IN and an output signal of the fifth inverter INV65. Third and fourth NMOS transistors NMOS63 and NMOS64 are connected in series between an output node NB and the ground voltage VSS and respond to output signals of the first and fourth inverters INV61 and INV64, respectively. A first PMOS transistor PMOS61 is connected in series between a boost voltage VPP and the control node NA and responds to a voltage level at the output node NB. And a second PMOS transistor PMOS62 is connected in series between the boost voltage VPP and the output node NB and responding to a voltage level at the control node NA.

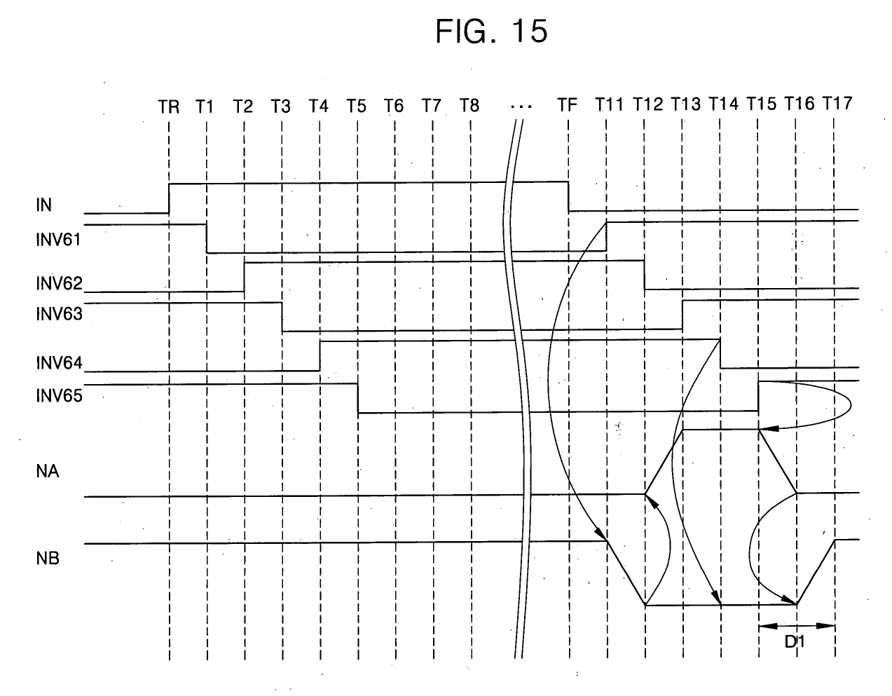

Referring to FIG. 15, it is assumed that the input signal IN is enabled from TR to TF. That is, the input signal IN transitions from a low level to a high level at TR and from a high level to a low level at TF.

The first inverter INV61 generates a signal transitioned from a high level to a low level at T1 and from a low level to a high level at T11. The second inverter INV62 generates a signal transitioned from a low level to a high level at T2 and from a high level to a low level at T12. The third inverter INV63 generates a signal transitioned from a high level to a low level at T3 and from a low level to a high level at T13. The fourth inverter INV64 generates a signal transitioned from a low level to a high level at T4 and from a high level to a low level at T14. And the fifth inverter INV65 generates a signal transitioned from a high level to a low level at T5 and from a low level to a high level at T15.

In the standby state, the first and fourth NMOS transistors NMOS61 and NMOS64 are turned off and the second and third NMOS transistors NMOS62 and NMOS63 are turned on, allowing current to flow through the second NMOS transistor NMOS62 and lowering the voltage level at the control node NA to the ground voltage VSS. The second PMOS transistor PMOS62 is turned on in response to the ground voltage VSS and the voltage level at the output node NB increases to the boost voltage VPP.

In the standby state, the control node NA of the level shift circuit has a level of the ground voltage VSS and the output node NB has a level of the boost voltage VPP.

At TR, the first, second, and third NMOS transistors NMOS61, NMOS62 and NMOS63 are all turned on and the fourth NMOS transistor NMOS64 is turned off, allowing current to flow through the first and second NMOS transistors NMOS61 and NMOS62.

Accordingly, the level shift circuit operates in the same manner as in the standby state, such that the output node NB has a level of the boost voltage VPP and the control node NA has a level of the ground voltage VSS.

This state does not change until the first inverter INV61 outputs a high level signal at T11.

At T11, the first and second NMOS transistors NMOS61 and NMOS62 are turned off and the third and fourth NMOS transistors NMOS63 and NMOS64 are turned on, allowing current to flow through the third and fourth NMOS transistors NMOS63 and NMOS64 and gradually lowering the voltage level at the output node NB.

At T12, the voltage level at the output node NB becomes the ground voltage VSS level and the level shift circuit generates an output signal OUT having the ground voltage VSS at the output node NB. At this state, the first PMOS transistor PMOS61 is turned on in response to the ground voltage VSS on the output node NB, allowing current to flow through the first PMOS transistor PMOS61 and gradually increasing the voltage level at the control node NA.

At T13, the voltage level at the control node NA becomes the boost voltage VPP level. At T14, the third NMOS transistor NMOS63 is turned on and the fourth NMOS transistor NMOS64 is turned on, such that the current flows through the output node NB. That is, at T14, the voltage level at the output node NB is fixed as the ground voltage VSS level.

When the fifth inverter INV65 outputs a high level signal at T15, the second NMOS transistor NMOS62 is turned on, allowing current to flow through the second NMOS transistor NMOS62 and gradually lowering the voltage level at the control node NA.

At T16, the voltage level at the control node NA becomes back the ground voltage VSS level, turning the second PMOS transistor PMOS62 on and increasing back the voltage level at the output node NB due to the current flowing through the second PMOS transistor PMOS62.

At T17, the voltage level at the output node NB becomes back the boost voltage VPP level and the level shift circuit generates back the output signal OUT having the boost voltage VPP at the output node NB.

As we describe above, the level shift circuit of FIG. 14 combines the input signal IN, the output signal of the first inverter INV61, the output signal of the fourth inverter INV64 and the output signal of the fifth inverter INV65 to generate a signal enabled in synchronization with the falling edge.

The level shift circuit reduces an input signal delay time D1 caused by the logic gates (e.g., the first NMOS transistor NMOS61 and the second PMOS transistor PMOS62) by performing the input signal width adjusting operation and the input signal level shifting operation in combination and reducing the number of stages of the logic gates needed for the two operations. Accordingly, the level shift circuit of FIG. 14 provides improved responsiveness, as in FIG. 4.

According to the present invention, the width of the input signal is adjusted and the input signal having the adjusted width is boosted by combining a plurality of delayed signals through one level shift circuit. That is, the level shift circuit of the present invention provides faster responsiveness by performing the input signal adjusting operation and the level shift operation in combination and reducing the number of the logic gates needed for the two operations.

In the drawings and specification, there have been disclosed typical preferred embodiments, although specific terms are employed, they are used in a generic and descriptive sense only and not for purposes of limitation, the scope of the following claims.

We claim the following:

1. A level shift circuit comprising:
a delay unit for delaying an input signal via a plurality of stages to generate a plurality of delayed signals; and
a signal width adjusting and level shifting unit for generating a first level of signal that is level-shifted in response to the input signal and a first delayed signal having the same phase as that of the input signal and generating a second level of signal in response to a second delayed signal having a different phase from that of the input signal.

2. The circuit according to claim 1, wherein the delay unit comprises an even number of inverters connected in series to generate the first delayed signal via an inverter connected to an even stage and the second delayed signal via an inverter connected to an odd stage.

3. The circuit according to claim 2, wherein the second delayed signal has a delay time shorter than that of the first delayed signal.

4. The circuit according to claim 1, wherein the first level is a boost voltage and the second level is a ground voltage.

5. The circuit according to claim 4, wherein the signal width adjusting and level shifting unit comprises:
first and second NMOS transistors connected in series between a control node and the ground voltage and responding to the input signal and the first delayed signal, respectively;
a third NMOS transistor connected in series between an output node and the ground voltage and responding to the second delayed signal;
a first PMOS transistor connected in series between the boost voltage and the control node to apply the boost voltage to the control node in response to a voltage level at the output node; and
a second PMOS transistor connected in series between the boost voltage and the output node to apply the boost voltage to the output node in response to the voltage level at the output node.

6. The circuit according to claim 2, wherein the delay unit further comprises a first inverter connected in series to an inverter of the last stage, and generates a third delayed signal having a different phase from that of the input signal via the first inverter.

7. The circuit according to claim 6, wherein the third delayed signal has a delay time longer than that of the first delayed signal.

8. The circuit according to claim 6, wherein the signal width adjusting and level shifting unit is connected in parallel to the third NMOS transistor, and further comprises a fourth NMOS transistor responding to the third delayed signal.

9. A level shift circuit comprising:
a delay unit for delaying an input signal via a plurality of stages to generate a plurality of delayed signals; and
a signal width adjusting and level shifting unit for generating a first level of shifted signal that is level-shifted in response to the input signal and generating a second level of signal in response to first and second delayed signals having a different phase from that of the input signal.

10. The circuit according to claim 9, wherein the delay unit comprises an odd number of inverters connected in series to generate the first and second delayed signals via first and second inverters connected to respective odd stages.

11. The circuit according to claim 9, wherein the first delayed signal has a delay time shorter than that of the second delayed signal.

12. The circuit according to claim 9, wherein the first level is a boost voltage and the second level is a ground voltage.

13. The circuit according to claim 9, wherein the signal width adjusting and level shifting unit comprises:
a first NMOS transistor connected in series between a control node and the ground voltage and responding to the input signal;
second and third NMOS transistors connected in series between an output node and the ground voltage and responding to the first and second delayed signals, respectively;
a first PMOS transistor connected in series between the boost voltage and the control node to apply the boost voltage to the control node in response to a voltage level at the output node; and
a second PMOS transistor connected in series between the boost voltage and the output node to apply the boost voltage to the output node in response to the voltage level at the output node.

14. The circuit according to claim 9, wherein the delay unit further comprises a third inverter connected in series to an inverter of the last stage, and generates a third delayed signal having the same phase as that of the input signal via the third inverter.

15. The circuit according to claim 14, wherein the third delayed signal has a delay time longer than that of the second delayed signal.

16. The circuit according to claim 14, wherein the signal width adjusting and level shifting unit is connected in parallel to the first NMOS transistor, and further comprises a fourth NMOS transistor responding to the third delayed signal.

17. A level shift circuit comprising:
a delay unit for delaying an input signal via a plurality of stages to generate a plurality of delayed signals; and
a signal width adjusting and level shifting unit for generating a first level of signal in response to the input signal and a first delayed signal having a different phase from that of the input signal and generating a second level of signal in response to a second delayed signal having a different phase from that of the input signal and a third delayed signal having the same phase as that of the input signal.

18. The circuit according to claim 17, wherein the delay unit comprises an even number of inverters connected in series to generate the first and second delayed signals via inverters connected to odd stages and the third delayed signal via an inverter connected to an even stage.

19. The circuit according to claim 18, wherein the third delayed signal has a delay time shorter than that of the first delayed signal and longer than that of the second delayed signal.

20. The circuit according to claim 17, wherein the first level is a boost voltage and the second level is a ground voltage.

21. The circuit according to claim 20, wherein the signal width adjusting and level shifting unit comprises:
first and second NMOS transistors connected in series between a control node and the ground voltage and responding to the input signal and the first delayed signal, respectively;
third and fourth NMOS transistors connected in parallel between an output node and the ground voltage and responding to the second delayed signal and the third delayed signal, respectively;
a first PMOS transistor connected in series between the boost voltage and the control node to apply the boost voltage to the control node in response to a voltage level at the output node; and
a second PMOS transistor connected in series between the boost voltage and the output node to apply the boost voltage to the output node in response to the voltage level at the output node.

22. The circuit according to claim 17, wherein the first level is a ground voltage and the second level is a boost voltage.

23. The circuit according to claim 22, wherein the signal width adjusting and level shifting unit comprises:
fifth and sixth NMOS transistors connected in parallel between the control node and the ground voltage and responding to the input signal and the first delayed signal, respectively;
seventh and eighth NMOS transistors connected in series between the output node and the ground voltage and responding to the second delayed signal and the third delayed signal, respectively;
a third PMOS transistor connected in series between the boost voltage and the control node to apply the boost voltage to the control node in response to a voltage level at the output node; and
a fourth PMOS transistor connected in series between the boost voltage and the output node to apply the boost voltage to the output node in response to the voltage level at the output node.

24. A level shift method comprising:
a delaying step of generating a plurality of delayed signals from an input signal;
a signal width adjusting step of adjusting the width of an output signal by transitioning the state of the output signal according to states of the input signal and the plurality of delayed signals; and
a level shifting step of allowing the output signal to have a first shifted level when the output signal is in a first state and to have a second level when the output signal is in a second state, and outputting the resultant output signal.

25. The method according to claim 24, wherein the first level is set as a boost voltage and the second level is set as a ground voltage.

26. The method according to claim 25, wherein the signal width adjusting step comprises:
generating an output signal in a first state in response to the input signal and a first delayed signal having the same phase as that of the input signal; and
transitioning the output signal from the first state to a second state in response to a second delayed signal having a different phase from that of the input signal.

27. The method according to claim 26, wherein the second delayed signal has a delay time shorter than that of the first delayed signal.

28. The method according to claim 25, wherein the signal width adjusting step comprises:
generating an output signal in a first state in response to the input signal; and
transitioning the output signal from the first state to the second state in response to first and second delayed signals having a different phase from that of the input signal.

29. The method according to claim 28, wherein the second delayed signal has a delay time longer than that of the first delayed signal.

30. The method according to claim 25, wherein the signal width adjusting step comprises:
generating the output signal in the first state in response to the input signal and a first delayed signal having a different phase from that of the input signal; and
transitioning the output signal from the first state to the second state in response to a second delayed signal having a different phase from that of the input signal and a third delayed signal having the same phase as that of the input signal.

31. The method according to claim 30, wherein the third delayed signal has a delay time shorter than that of the first delayed signal and longer than that of the second delayed signal.

32. The method according to claim 25, wherein the signal width adjusting step comprises:
generating the output signal in the second state in response to the input signal and a first delayed signal having a different phase from that of the input signal; and
generating a signal transitioned from the second state to the first state in response to a second delayed signal having a different phase from that of the input signal and a third delayed signal having the same phase as that of the input signal.
